(19) United States
(12) Patent Application Publication
(10) Pub. No.: US 2018/0076269 A1
(43) Pub. Date: Mar. 15, 2018

(54) METHOD FOR MANUFACTURING DISPLAY DEVICE

(71) Applicant: Japan Display Inc., Tokyo (JP)

(72) Inventor: Tomohiko NAGANUMA, Tokyo (JP)

(21) Appl. No.: 15/822,255

(22) Filed: Nov. 27, 2017

Related U.S. Application Data
(62) Division of application No. 15/290,591, filed on Oct. 11, 2016.

(30) Foreign Application Priority Data
Nov. 16, 2015 (JP) 2015-223815

(51) Int. Cl. H01L 27/32; H01L 51/50; H01L 51/56; H01L 51/52

(52) U.S. Cl. CPC H01L 27/3246; H01L 2227/323; H01L 51/5072; H01L 51/5056; H01L 51/56; H01L 51/5268; H01L 27/326; H01L 51/5203; H01L 27/3276

(57) ABSTRACT

There is provided a display device including a plurality of pixels, a bank layer located at boundaries among the plurality of pixels and separating each of the plurality of pixels, lower electrodes respectively provided in the plurality of pixels, a light emitting layer arranged on at least a lower electrode of the lower electrodes, and an upper electrode arranged on the light emitting layer, in which the light emitting layer has a first surface opposing the lower electrode, a second surface located on an opposite side of the light emitting layer from the first surface, and a side surface intersecting the first surface and the second surface, and the bank layer is located on an opposite side of the light emitting layer from the lower electrode and covers a part of the second surface and the side surface of the light emitting layer.

### CROSS REFERENCE TO RELATED APPLICATIONS

This application is based upon and claims the benefit of priority from the prior Japanese Patent Application No. 2015-223815 filed on Nov. 16, 2015, the entire contents of which are incorporated herein by reference.

### FIELD

The present invention relates to a display device and a method for manufacturing the display device. Particularly, it relates to a display device having a light emitting layer patterned for each pixel and a method for manufacturing the display device.

### BACKGROUND

An organic electroluminescence display device, in which an organic layer including a light emitting layer and a carrier transport layer (a hole transport layer and an electron transport layer) is arranged between an upper electrode and a lower electrode, has been known. A display device using quantum dots, in which light emitting layers including a nanoscale luminescent material are respectively arranged, between an upper electrode and a lower electrode has also been known. In these display devices, a plurality of light emitting elements are respectively provided in pixels, and the respective light emissions of the light emitting layers are individually controlled, to display an image. In these display devices, the lower electrode is provided for each of the plurality of pixels, and the upper electrode is provided to extend across the plurality of pixels, for example. A signal voltage corresponding to a video signal is applied to the lower electrodes, and a predetermined common voltage is applied to the upper electrode, to control the light emissions of the light emitting elements.

A configuration in which the light emitting layers in each of the display devices are respectively formed independently in the plurality of pixels has been known. The plurality of pixels are separated by bank layers (insulating layers) respectively located at boundaries among the plurality of pixels. The bank layer includes an opening which is formed on an upper layer of the lower electrode and exposes a portion of the lower electrode. The light emitting layer contacts the exposed portion of the lower electrode while being formed on an upper layer of the bank layer. Japanese Patent Application Laid-Open No. 2012-109426 discloses an organic electroluminescence display device including a lower electrode, an upper electrode, a bank layer, and a light emitting layer formed to contact a portion, exposed from the bank layer, of the lower electrode while contacting side surfaces of the bank layer within an opening of the bank layer.

In the aforementioned display device, the light emitting layer may be formed by coating in an entire area or a substantially entire area on a substrate and then patterned into a predetermined shape. The light emitting layers after patterning using a similar patterning method may be respectively arranged independently in the plurality of pixels.

### SUMMARY

A display device in an embodiment according to the present invention includes a plurality of pixels, a bank layer located at boundaries among the plurality of pixels and separating each of the plurality of pixels, lower electrodes respectively provided in the plurality of pixels, a light emitting layer arranged on at least a lower electrode of the lower electrodes, and an upper electrode arranged on the light emitting layer, in which the light emitting layer has a first surface opposing the lower electrode, a second surface located on an opposite side of the light emitting layer from the first surface, and a side surface intersecting the first surface and the second surface, and the bank layer is located on an opposite side of the light emitting layer from the lower electrode and covers a part of the second surface and the side surface of the light emitting layer.

A method for manufacturing display device in an embodiment according to the present invention includes a lower electrode formation step of forming a lower electrode on a substrate, a coating step of coating the substrate with a light emitting layer, a light emitting layer patterning step of patterning the light emitting layer into an island-shaped pattern at least a part of which overlaps the lower electrode, an insulating layer formation step of forming an insulating layer which covers an upper surface and a side surface of the light emitting layer after the light emitting layer patterning step, an opening formation step of forming an opening in the insulating layer, the opening exposing a part of the upper surface of the light emitting layer, and an upper electrode formation step of forming an upper electrode located on the insulating layer and contacting the light emitting layer via the opening.

### BRIEF DESCRIPTION OF THE DRAWINGS

FIG. 1 is a perspective view illustrating a configuration of a display device according to a first embodiment of the present invention;

FIG. 2 is a cross-sectional view illustrating the configuration of the display device according to the first embodiment of the present invention;

FIG. 3 is a cross-sectional view illustrating a method for manufacturing the display device according to the first embodiment of the present invention;

FIG. 4 is a cross-sectional view illustrating the method for manufacturing the display device according to the first embodiment of the present invention;

FIG. 5 is a cross-sectional view illustrating the method for manufacturing the display device according to the first embodiment of the present invention;

FIG. 6 is a cross-sectional view illustrating the method for manufacturing the display device according to the first embodiment of the present invention;

FIG. 7 is a cross-sectional view illustrating the method for manufacturing the display device according to the first embodiment of the present invention;

FIG. 8 is a cross-sectional view illustrating the method for manufacturing the display device according to the first embodiment of the present invention;

FIG. 9 is a cross-sectional view illustrating the method for manufacturing the display device according to the first embodiment of the present invention;

FIG. 10 is a cross-sectional view illustrating the method for manufacturing the display device according to the first embodiment of the present invention;

FIG. 11 is a cross-sectional view illustrating a configuration of a display device according to a second embodiment of the present invention;

FIG. 12 is a cross-sectional view illustrating a configuration of a display device according to a third embodiment of the present invention;

FIG. 13 is a cross-sectional view illustrating a configuration of a display device according to a fourth embodiment of the present invention;

FIG. 14 is a cross-sectional view illustrating a configuration of a display device according to a fifth embodiment of the present invention;

FIG. 15 is a cross-sectional view illustrating the configuration of the display device according to the fifth embodiment of the present invention;

FIG. 16 is a cross-sectional view illustrating a configuration of a display device according to a sixth embodiment of the present invention; and

FIG. 17 is a cross-sectional view illustrating a problem in the display device.

### DESCRIPTION OF EMBODIMENTS

Embodiments of the present invention will hereinafter be described with reference to the drawings. However, the present invention can be implemented in many different modes, and is not to be interpreted as being limited to contents of description of embodiments illustrated below. While the width, the thickness, the shape, and the like of each of portions may be more schematically indicated than those in an actual mode to make the description clearer, this is only one example, and is not to limit the interpretation of the present invention. In the present specification and the drawings, detailed description may be omitted, as needed, by assigning similar elements to those described above with reference to the already described drawing the same reference signs.

In the present specification, when a member or region exists “on (or under)” another member or region, this includes not only a case where the member or region exists just above (or just below) the other member or region but also a case where the member or region exists above (or below) the other member or region, i.e., includes a case where another component is included between the member or region above (below) the other member or region and the other member or region except as otherwise limited.

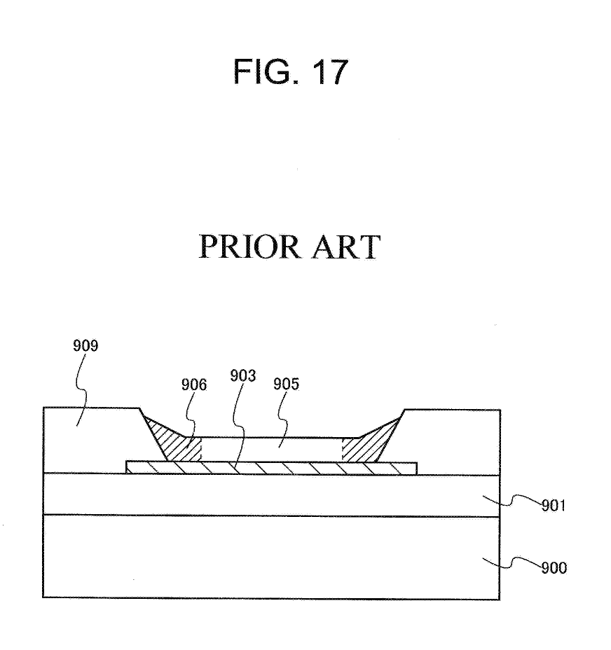

FIG. 17 illustrates a problem in forming by coating a light emitting layer and patterning the formed light emitting layer, and respectively arranging light emitting layers after the patterning independently in a plurality of pixels. FIG. 17 is a cross-sectional view illustrating a structure of a light emitting layer and its periphery. A lower electrode 903 electrically connected to a circuit layer 901 is arranged on a substrate 900. A bank layer 909 covers a peripheral portion of the lower electrode 903 while having an opening which exposes a central portion of the lower electrode 903. A light emitting layer 905 is formed by coating in contact with the lower electrode 903 in the opening of the bank layer 909.

When the opening in the bank layer 909 is formed, and is then coated with a solution material to be the light emitting layer 905, the thickness of the solution material in a region contacting the bank layer 909 and a region located in the vicinity of the bank layer 909 is larger than that in a central portion of the opening and a region located in the vicinity of the central portion due to the influence of surface tension on side surfaces of the bank layer 909. As a result, even in the light emitting layer 905, a thick film portion 906 having a larger film thickness than that in the central portion of the opening occurs in the vicinity of the bank layer 909. A light emitting property of a light emitting element is significantly sensitive to the film thickness of the light emitting layer 905. Accordingly, if the thick film portion 906 occurs in the light emitting layer 905 so that the film thickness of the light emitting layer 905 becomes less uniform, the light emitting property also becomes less uniform. As a result, in a configuration according to a conventional technique illustrated in FIG. 17, luminance non-uniformity within each of the pixels and non-uniformity in light emitting property between the pixels occur, resulting in a deteriorated image quality.

### First Embodiment

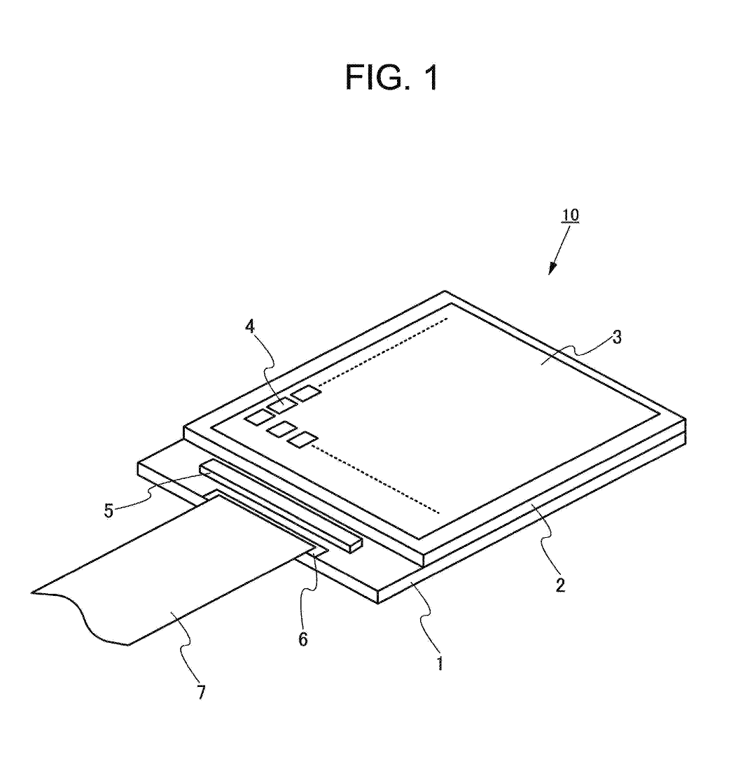

A configuration of a display device 10 according to a first embodiment will be described with reference to FIG. 1. The display device 10 includes an array substrate 1, in which a light emitting element, a circuit including a thin film transistor (hereinafter referred to as a “TFT”) and various types of wirings, and the like are formed, and an opposite substrate 2 arranged opposite to the array substrate 1 and stuck thereto. The array substrate 1 includes a region not overlapping the opposite substrate 2, and the region is provided with a driver integrated circuit (IC) 5 and a terminal region 6 in which a plurality of terminals, which connect a wiring for supplying a video signal or a driving pulse signal from the outside, a power supply voltage, or the like and a wiring of the display device 10, are arranged. A flexible printed board (FPC) 7 is connected to the terminal region 6.

Further, the display device 10 includes a display region 3, and the display region 3 includes a plurality of pixels 4. Each of the plurality of pixels 4 includes a light emitting layer, described below, and corresponds to one dot of an image to be displayed in the display region 3 by the display device 10. The pixel 4 may also be called a sub-pixel. Some of the pixels 4, e.g., the three pixels 4, i.e., the pixel for emitting light in red, the pixel for emitting light in green, and the pixel for emitting light in blue constitute one unit of the pixel.

A filling material may be arranged in a gap between the array substrate 1 and the opposite substrate 2. A color filter may be arranged in the opposite substrate 2. A circularly polarizing plate or a protective sheet may be arranged on a surface of the opposite substrate 2. Further, a touch panel or a cover glass may be arranged on the surface of the opposite substrate 2.

The opposite substrate 2 need not necessarily be provided in the display device 10. For example, the opposite substrate 2 may be replaced with the aforementioned filling material or an organic film (sealing film) arranged to cover the light emitting layer or the like on the array substrate 1. The opposite substrate 2 may be replaced with the aforementioned circularly polarizing plate or protective sheet.

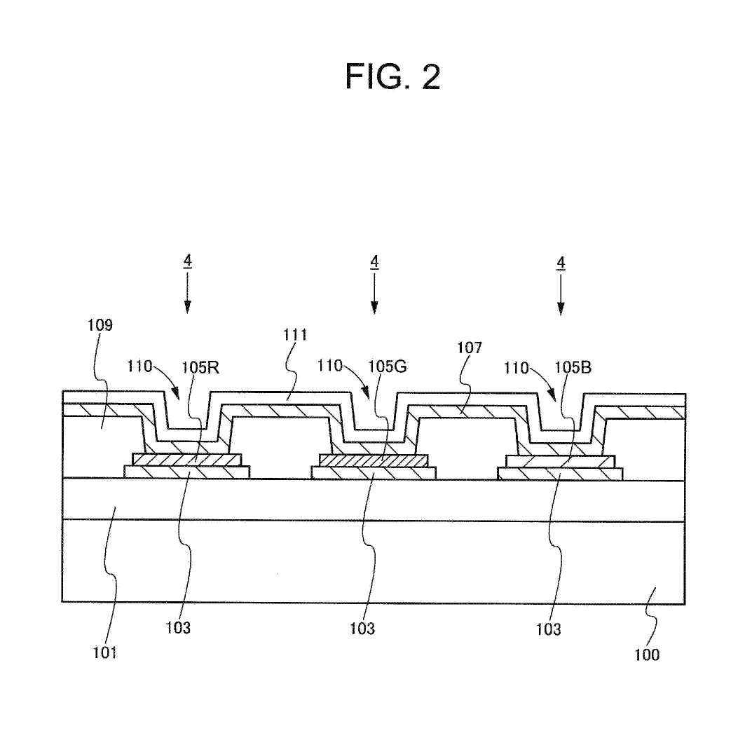

FIG. 2 is a cross-sectional view of the plurality of pixels 4 illustrated in FIG. 1. FIG. 2 illustrates the three pixels 4 arranged side by side.

As illustrated in FIG. 2, a circuit layer 101 is provided on a substrate 100. Examples of the substrate 100 include a glass substrate and a resin substrate. The resin substrate may be a substrate mainly composed of polyimide, for example, and having flexibility. The substrate 100 may have a structure in which a plurality of organic layers (resin layers mainly composed of polyimide, for example) are laminated and an inorganic layer is located between the organic layers.

The circuit layer 101 includes a driving circuit which is arranged in a peripheral region surrounding the display region 3 and drives the display device 10, a pixel circuit which is arranged in the display region 3 and controls an operation of the pixels 4, and various types of wirings. Each of the driving circuit and the pixel circuit includes a plurality of TFTs. In FIG. 2, the circuit layer 101 also includes an interlayer insulating film formed of an organic film or an inorganic film and provided on an upper layer and a lower layer of each of the various types of wirings and various types of electrodes of the TFTs, an underlying film located just above the substrate 100, and a flattening film which flattens irregularities of the TFTs and the wirings.

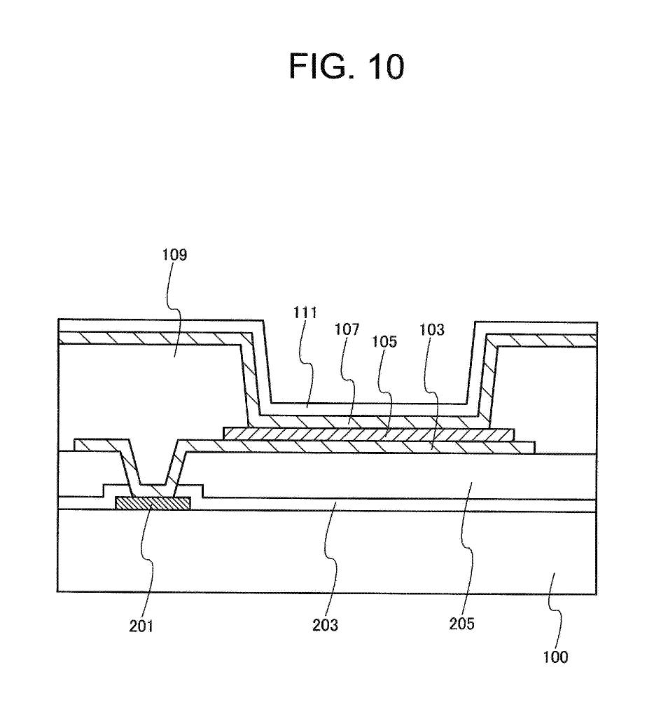

A lower electrode 103 is provided on the circuit layer 101. The lower electrode 103 is patterned into a predetermined shape, and lower electrodes 103 after the patterning are respectively arranged in the pixels 4. The lower electrode 103 is formed of a transparent conductive film composed of ITO (indium tin oxide), for example. The lower electrode 103 may be formed of a reflective film composed of a metal such as silver, or may be formed of a laminated structure of a transparent conductive film and a reflective film. The lower electrode 103 is connected to a source-drain electrode 201 of the TFT formed in the circuit layer 101, illustrated in FIG. 10, described below, and a signal voltage corresponding to a video signal is applied to the lower electrode 103.

A light emitting layer 105 (105R, 105G, 105B) is provided on the lower electrodes 103. The light emitting layer 105 is a light emitting layer which enters an excited state by recombining electrons and holes and emits fluorescence when it returns from the excited state to a ground state in an organic electroluminescence display device, for example. The light emitting layer 105 may be a light emitting layer including a nanoscale luminescent material in a display device using quantum dots. The light emitting layer 105 is formed by coating an entire surface or a substantially entire surface of the substrate 100 with a solution material. Then, the light emitting layer 105 is patterned into a predetermined shape, and light emitting layers 105 after the patterning are respectively arranged in the pixels 4. While the light emitting layer 105 is patterned by photolithography, for example, another patterning method may be used. The light emitting layer 105 may be formed by an ink jet method. If the light emitting layer 105 is formed by the ink jet method, the above described patterning process is not required.

The three light emitting layers 105 arranged side by side may differ in luminescent color. In FIG. 2, the light emitting layer 105R having a red luminescent color, the light emitting layer 105G having a green luminescent color, and the light emitting layer 105B having a blue luminescent color are arranged. When the light emitting layers 105 differ in luminescent color, respective solution materials serving as materials for the light emitting layers 105 also differ. Accordingly, for each of the light emitting layers 105R, 105G, and 105B, a film formation process by coating with the solution material and a patterning process for pattering into a predetermined shape may be performed.

In the first embodiment, the light emitting layer 105 may be formed of laminated films each including a carrier transport layer (a hole transport layer and an electron transport layer) and a carrier injection layer (a hole injection layer and an electron injection layer). In this case, the light emitting layer 105 may be patterned by sequentially film-forming the laminated films.

A bank layer 109 is provided on respective upper layers of the lower electrode 103 and the light emitting layer 105. The bank layers 109 are respectively located at boundaries among the plurality of pixels 4, to separate the plurality of pixels 4. The bank layer 109 is formed of an insulating film, and is formed of an organic film composed of photosensitive acrylic, for example. The bank layer 109 may be formed of an inorganic film composed of silicon oxide or silicon nitride, for example. The bank layer 109 runs onto a portion of the light emitting layer 105, e.g., onto a peripheral portion of the light emitting layer 105. In other words, the bank layer 109 is located on the opposite side to the lower electrode 103 with the light emitting layer 105 interposed therebetween, to cover the portion of the light emitting layer 105.

Furthermore, the bank layer 109 exposes another portion of the light emitting layer 105, e.g., a central portion including the center of the light emitting layer 105. An opening 110 which exposes the other portion is formed in the bank layer 109. The bank layer 109 is flattened without following respective shapes of the lower electrode 103 and the light emitting layer 105, except for its portion of the opening 110, as illustrated in FIG. 2. However, the present invention is not limited to this configuration. The configuration may be replaced with a configuration in which the bank layer 109 has a step in its region overlapping an end portion of the light emitting layer 105 by following the respective shapes of the lower electrode 103 and the light emitting layer 105, for example.

As described above, the bank layer 109 is prepared by covering the light emitting layer 105, i.e., being superimposed on the light emitting layer 105 in a planar view after the light emitting layer 105 is formed. Further, the opening 110, which exposes the other portion of the light emitting layer 105, is formed in the bank layer 109 after the bank layer 109 is formed.

An upper electrode 107 is provided on an upper layer of the bank layer 109. The upper electrode 107 is arranged to extend across the plurality of pixels 4 beyond the bank layers 109. The upper electrode 107 is formed of a transparent conductive film composed of IZO (indium zinc oxide), for example, or a metal film containing magnesium and silver, for example. A predetermined common voltage is applied to the upper electrode 107. As illustrated in FIG. 2, a portion, exposed from the bank layer 109, of the light emitting layer 105 by the opening 110 in the bank layer 109 and the upper electrode 107 are electrically connected to each other. In FIG. 2, the upper electrode 107 directly contacts the portion, exposed from the bank layer 109, of the light emitting layer 105.

The upper electrode 107, the lower electrode 103, and the light emitting layer 105 located between the upper electrode 107 and the lower electrode 103 form a light emitting element in each of the plurality of pixels 4. To the lower electrode 103 provided in each of the plurality of pixels 4, a signal voltage corresponding to the video signal input to the pixel 4 is applied. As a result, when the respective light emissions of the plurality of light emitting elements are individually controlled, the display device 10 displays an image.

A sealing layer 111 is provided on the upper electrode 107. The sealing layer 111 covers the light emitting layers 105, and is arranged to extend across the plurality of pixels 4 beyond the bank layers 109. The sealing layer 111 may be formed of an inorganic insulating film composed of silicon nitride, for example. The sealing layer 111 may have a laminated structure of an inorganic insulating film and an organic insulating film composed of alkali resin, for example. The sealing layer 111 is provided to prevent water from the outside from entering the light emitting layers 105.

In the present embodiment, the bank layer 109 covering the light emitting layer 105 is formed after the light emitting layer 105 is formed, as described above. Further, in the present embodiment, the light emitting layer 105 is exposed by the opening 110 formed in the bank layer 109.

More specifically, in the present embodiment, the light emitting layer 105 is formed before the bank layer 109 is formed. Therefore, the film thickness portion 106, as illustrated in FIG. 17, is not formed in the light emitting layer 105. Accordingly, the film thickness of the light emitting layer 105 can be made uniform. Consequently, luminance non-uniformity in each of the pixels 4 and non-uniformity in light emitting property between the pixels 4 can be inhibited and prevented, resulting in an improved image quality. The film thickness of the light emitting layer 105 is desirably flattened until a difference in film thickness between a site having the largest film thickness and a site having the smallest film thickness of the light emitting layer 105 becomes 10% or less, for example, of the film thickness of the site having the smallest film thickness of the light emitting layer 105. The film thickness of the light emitting layer 105 is more desirably flattened until the difference in film thickness becomes less than 5% of the film thickness of the site having the smallest film thickness of the light emitting layer 105.

To solve the luminance non-uniformity in the pixel, a measure to apply a high current for saturating the luminance of the light emitting element and cancel the non-uniformity has been known. However, the measure has a disadvantage in that power consumption becomes higher than necessary. In the present embodiment, the luminance non-uniformity is prevented without the power consumption being increased, enabling the image quality to be improved.

In FIG. 2, the lower electrode 103 is formed to be larger than the light emitting layer 105. In other words, an end portion of the light emitting layer 105 is located inside an end portion of the lower electrode 103. Such a configuration enables the electrode of the TFT in the circuit layer 101 (e.g., a source-drain electrode 201 of a TFT illustrated in FIG. 10) and the lower electrode 103 to be connected to each other in a region, not overlapping the light emitting layer 105, of the lower electrode 103, as illustrated in FIG. 10, described below. Alternatively, the end portion of the light emitting layer 105 and the end portion of the lower electrode 103 may overlap each other in a planar view, i.e., the light emitting layer 105 and the lower electrode 103 may be of the same size.

### Manufacturing Method According to First Embodiment

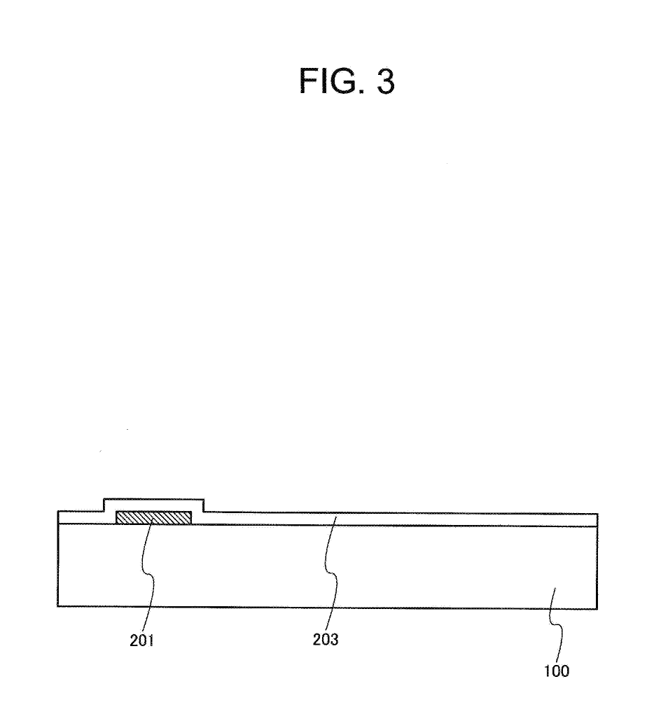

A manufacturing method according to the present embodiment will be described with reference to FIG. 3 to FIG. 10. FIG. 3 to FIG. 10 are cross-sectional views illustrating the manufacturing method according to the present embodiment. In FIG. 3 to FIG. 10, among TFTs and various types of wirings included in the circuit layer 101 illustrated in FIG. 2, only an electrode connected to the lower electrode 103 and an insulating film on the electrode will be described.

As illustrated in FIG. 3, various types of circuits and wirings including a source-drain electrode 201 of a TFT provided in each of pixels 4 are formed on a substrate 100. An interlayer insulating film 203 including an inorganic insulating film is formed on the source-drain electrode 201.

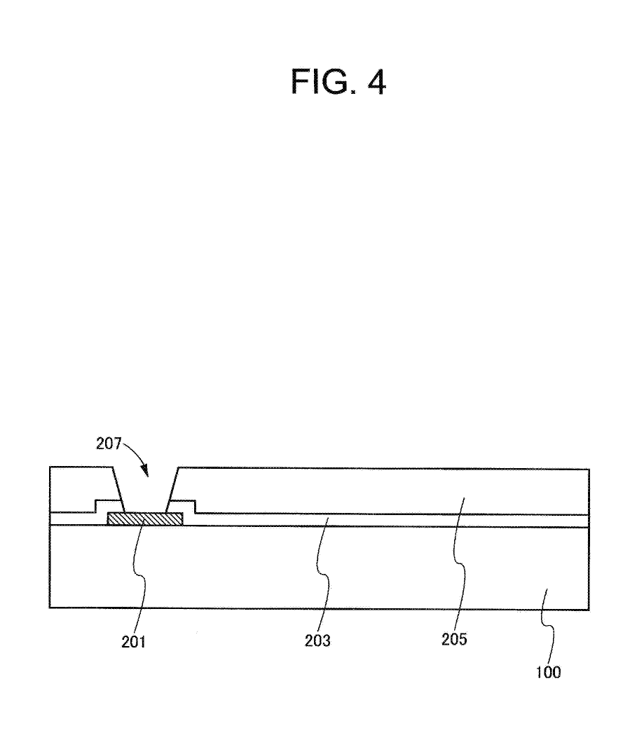

As illustrated in FIG. 4, a flattening film 205 including an organic insulating film is formed on the interlayer insulating film 203. A contact hole 207, which penetrates the interlayer insulating film 203 and the flattening film 205 and exposes a source-drain electrode 201, is formed on the source-drain electrode 201.

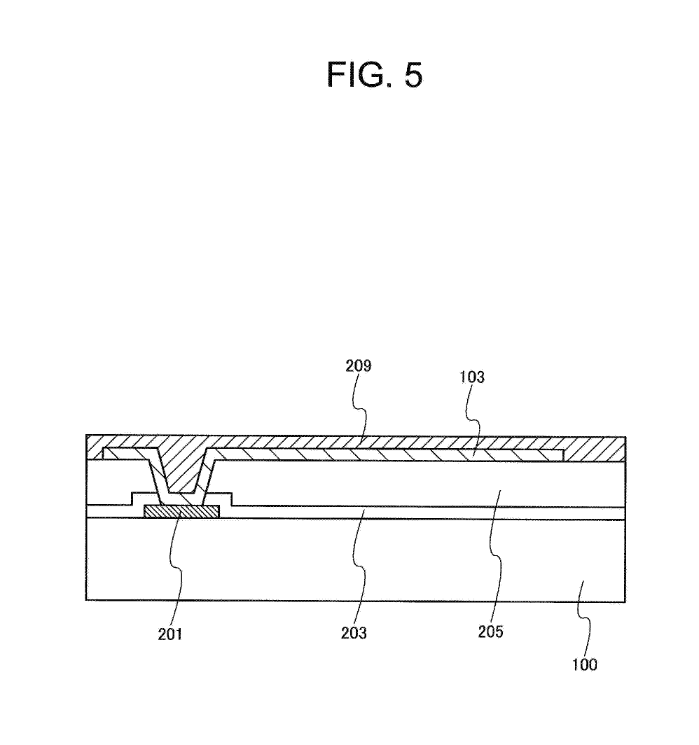

As illustrated in FIG. 5, a lower electrode 103, which contacts the source-drain electrode 201 via the contact hole 207, is formed. The lower electrode 103 is formed in an entire area or a substantially entire area of the substrate 100, and is patterned into a predetermined shape. After the lower electrode 103 is formed, a solution to be a material for a light emitting layer 105 is applied to the entire area or a substantially entire area of the substrate 100, to film-form an organic film 209 which has not been patterned. The contact hole 207 is filled with the organic film 209.

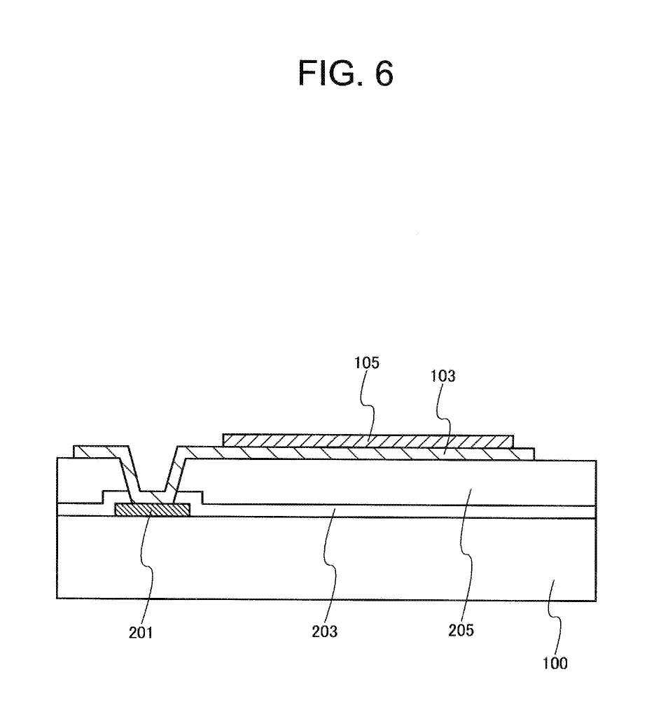

As illustrated in FIG. 6, the organic film 209 is patterned by photolithography, to form a light emitting layer 105 on the lower electrode 103. The organic film 209 may be patterned using another patterning method other than photography.

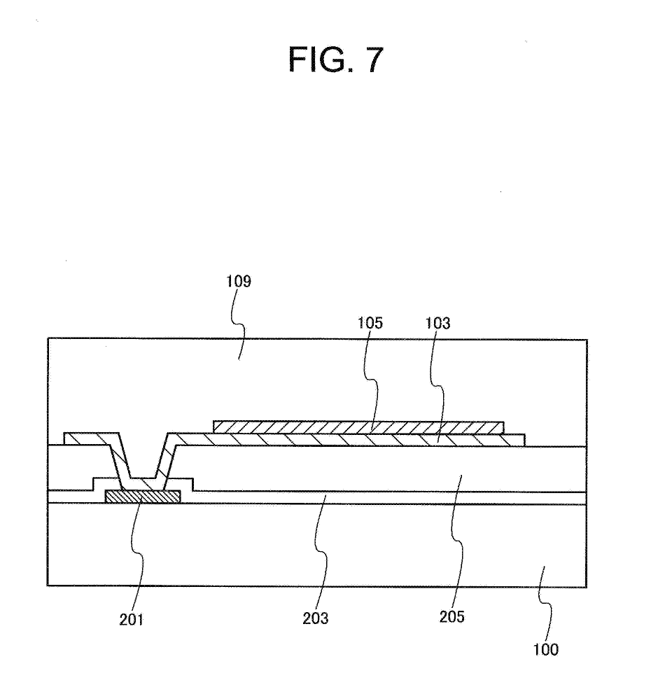

As illustrated in FIG. 7, a bank layer 109 is formed to cover the lower electrode 103 and the light emitting layer 105. In FIG. 7, the bank layer 109 is formed in the entire area or a substantially entire area of the substrate 100.

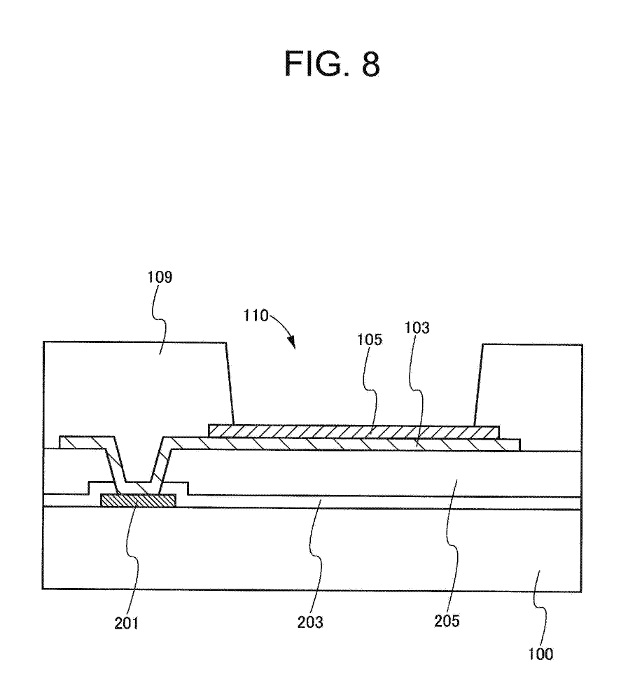

As illustrated in FIG. 8, the bank layer 109, which has been formed in the entire area or the substantially entire area of the substrate 100, is patterned. The bank layer 109 is located so that bank layers 109 after the patterning are located at boundaries among the plurality of pixels 4 illustrated in FIG. 1 to separate the plurality of pixels 4. An opening 110 is formed in the bank layer 109 so that the bank layer 109 runs onto a peripheral portion of the light emitting layer 105 and exposes a central portion of the light emitting layer 105. The opening 110 is formed simultaneously with the patterning for separating the plurality of pixels 4.

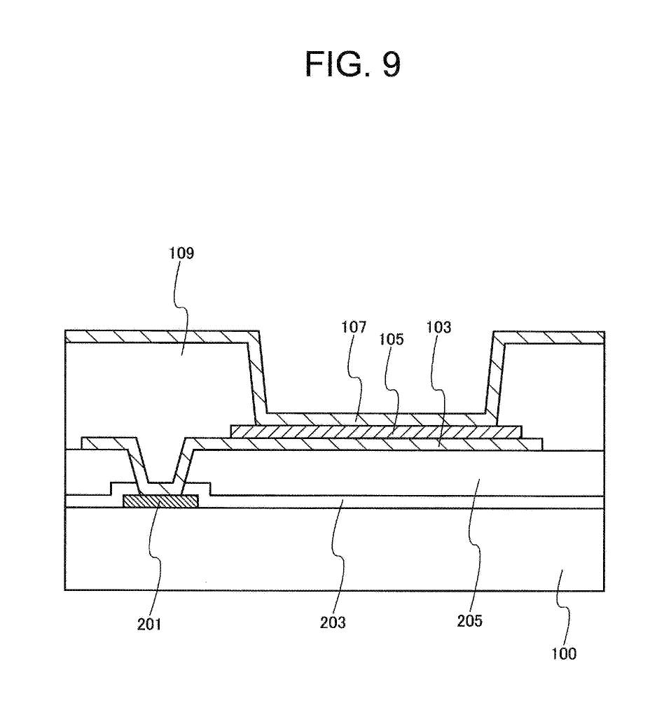

As illustrated in FIG. 9, an upper electrode 107 is formed to cover the bank layer 109. The upper electrode 107 is formed to be arranged to extend across the plurality of pixels 4 beyond the bank layer 109.

As illustrated in FIG. 10, a sealing layer 111 is formed on the upper electrode 107. The sealing layer 111 is formed to cover the light emitting layer 105 and to be arranged to extend across the plurality of pixels 4 beyond the bank layers 109.

In the manufacturing method according to the present embodiment, a process for forming the light emitting layer 105 is prior to a process for forming the bank layer 109, as described above. Therefore, the thick film portion 106 illustrated in FIG. 17 can be prevented from occurring in the light emitting layer 105.

### Second Embodiment

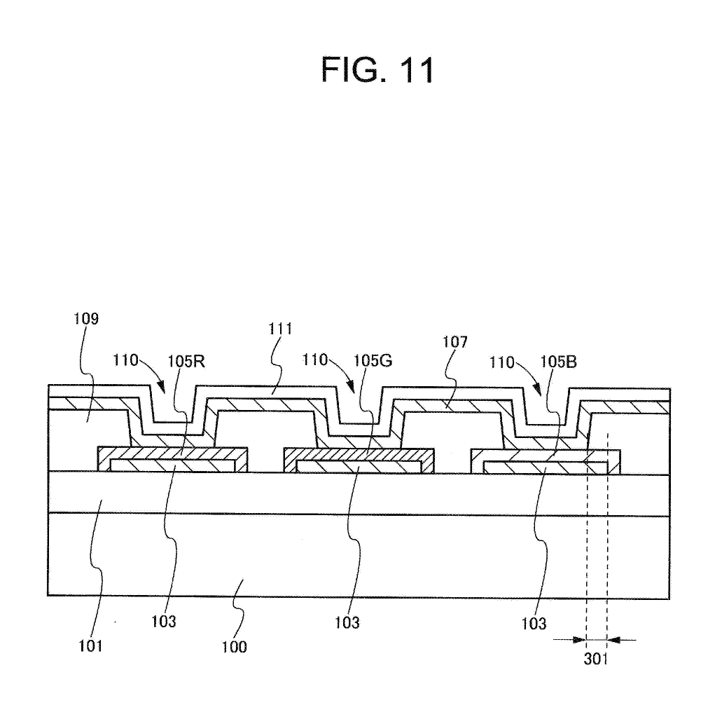

A configuration according to a second embodiment will be described with reference to FIG. 11. The second embodiment differs from the first embodiment in a positional relationship and a size relationship between a lower electrode 103 and a light emitting layer 105 (105R, 105G, 105B).

In the second embodiment, the light emitting layer 105 is formed to cover the entire lower electrode 103. More specifically, the light emitting layer 105 is larger than the lower electrode 103 in a planar view. In other words, an end portion of the light emitting layer 105 is located outside an end portion of the lower electrode 103.

In such a configuration, the lower electrode 103 is covered with the light emitting layer 105 formed immediately after being formed. More specifically, even in a state where a bank layer 109 has not been formed, when the lower electrode 103 is covered with the light emitting layer 105, an exposed portion of the lower electrode 103 can be reduced. Accordingly, the lower electrode 103 can be prevented from being unintentionally short-circuited during manufacturing processes.

In the processes for manufacturing a display device, various components on a substrate are charged during the process, and an unintended discharge phenomenon may occur in a metal (also including the lower electrode 103) on the substrate from each of the charged components. In the configuration according to the second embodiment, the aforementioned discharge phenomenon can be prevented by covering the lower electrode 103 with the light emitting layer 105.

The lower electrode 103 desirably includes an overlap region 301 where it is superimposed on the bank layer 109 in a planar view. This is for making the whole of a portion, which is exposed by the bank layer 109, of the light emitting layer 105 and the lower electrode 103 oppose each other to use the whole of the portion of the light emitting layer 105 as a light emitting region.

### Third Embodiment

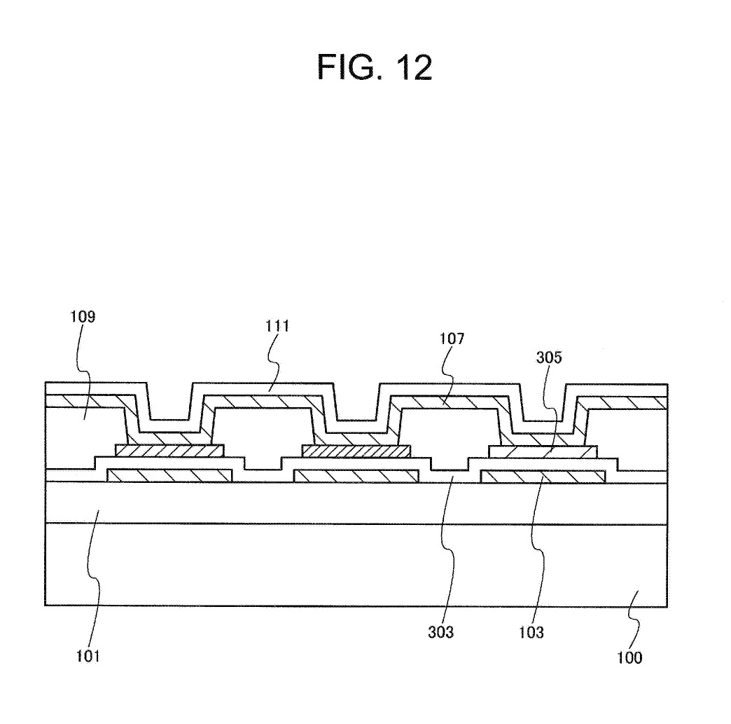

A configuration according to a third embodiment will be described with reference to FIG. 12. The third embodiment differs from the first embodiment in a structure of a light emitting layer on a lower electrode 103.

In an organic electroluminescence display device, a light emitting element includes an anode (e.g., a lower electrode), a cathode (e.g., an upper electrode), and an organic layer sandwiched between the anode and the cathode. The organic layer includes a light emitting layer serving as a region where electrons and holes are recombined with each other and a carrier transport layer located between the light emitting layer and the electrode. The carrier transport layer includes a hole transport layer located between the light emitting layer and the anode and an electron transport layer located between the light emitting layer and the cathode. The organic layer may include a carrier injection layer (a hole injection layer and an electron injection layer) located between the carrier transport layer and the electrode.

In the third embodiment, a first carrier transport layer 303 is provided on lower electrodes 103, as illustrated in FIG. 12. Further, light emitting layers 305 are located between the first carrier transport layer 303 and an upper electrode 107.

If a display device illustrated in FIG. 12 is an organic electroluminescence display device, a region where electrons and holes are recombined with each other is included in the light emitting layers 305. If the lower electrode 103 is an anode, the first carrier transport layer 303 is a hole transport layer.

As illustrated in FIG. 12, the first carrier transport layer 303 covers an upper surface and side surfaces of each of the lower electrodes 103, and is arranged to extend across a plurality of pixels 4. Even if light emitting elements differ in luminescent color, a material for the first carrier transport layer 303 can be used to be common among the light emitting elements. Accordingly, the first carrier transport layer 303 need not be arranged independently in each of the plurality of pixels 4.

In the third embodiment, the first carrier transport layer 303 is not patterned but is arranged to extend across the plurality of pixels 4. Therefore, manufacturing processes can be simplified, throughput can be shortened, and quantity production can be improved.

A carrier injection layer may be provided between the first carrier transport layer 303 and the lower electrodes 103. If the first carrier transport layer 303 is a hole transport layer, the carrier injection layer is a hole injection layer.

### Fourth Embodiment

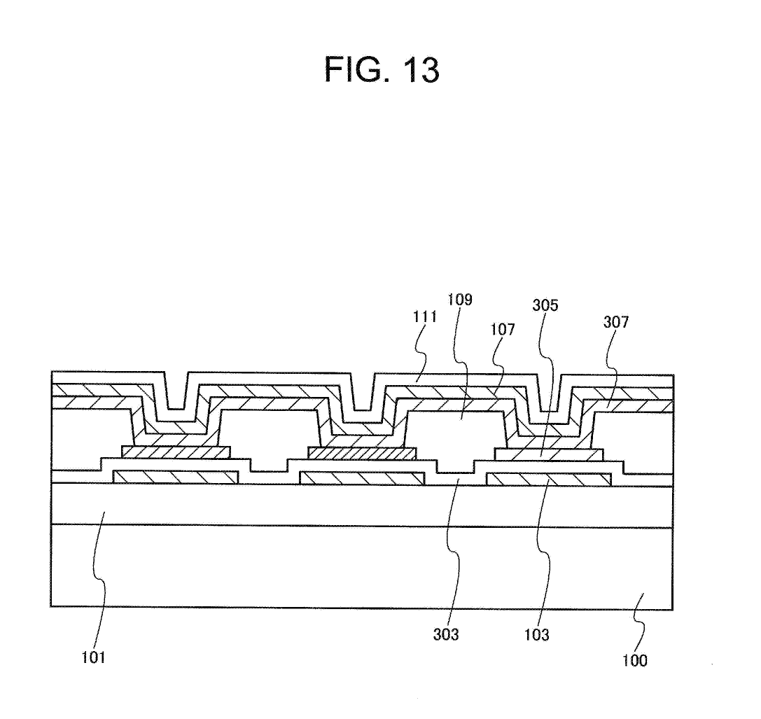

A configuration according to a fourth embodiment will be described with reference to FIG. 13. The fourth embodiment differs from the third embodiment in a structure of a carrier transport layer. In the fourth embodiment, a second carrier transport layer 307 is provided between light emitting layers 305 and an upper electrode 107, as illustrated in FIG. 13.

If a display device illustrated in FIG. 13 is an organic electroluminescence display device, a region where electrons and holes are recombined with each other is included in the light emitting layer 305. If the upper electrode 107 is a cathode, the second carrier transport layer 307 is an electron transport layer.

As illustrated in FIG. 13, the second carrier transport layer 307 is arranged to extend across a plurality of pixels 4 beyond bank layers 109. Even if light emitting elements differ in luminescent color, a material for the second carrier transport layer 307 can be used to be common among the light emitting elements, like for a first carrier transport layer 303. Accordingly, the second carrier transport layer 307 need not be arranged independently in each of the plurality of pixels 4.

In the fourth embodiment, the second carrier transport layer 307 is not patterned but is arranged to extend across the plurality of pixels 4. Therefore, manufacturing processes can be simplified, throughput can be shortened, and quantity production can be improved.

A carrier injection layer may be provided between the second carrier transport layer 307 and the upper electrode 107. If the second carrier transport layer 307 is an electron transport layer, the carrier injection layer is an electron injection layer.

In FIG. 13, while both the first carrier transport layer 303 and the second carrier transport layer 307 are arranged to extend across the plurality of pixels 4, the present invention is not limited to this configuration. The configuration may be replaced with a configuration in which the first carrier transport layer 303 is arranged independently in each of the plurality of pixels 4 and only the second carrier transport layer 307 is arranged to extend across the plurality of pixels 4.

### Fifth Embodiment

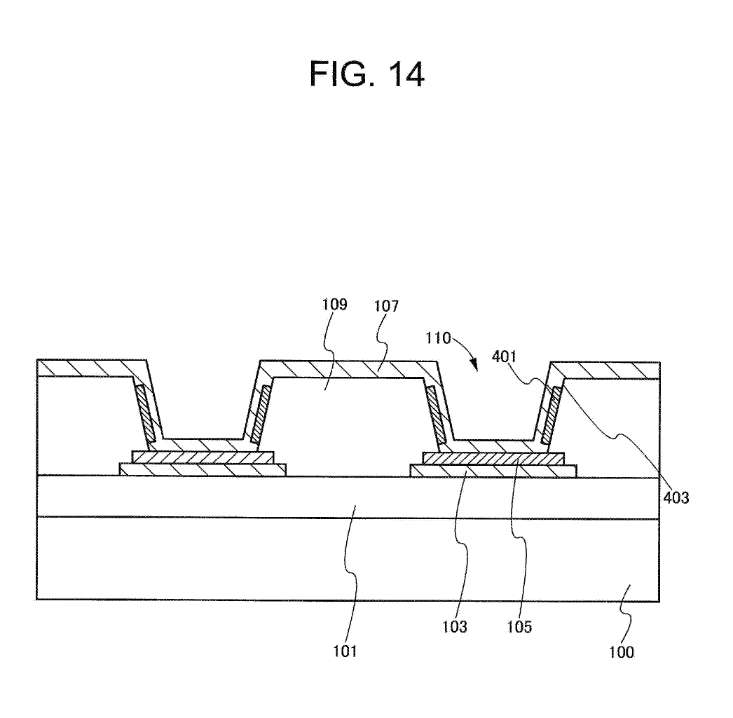

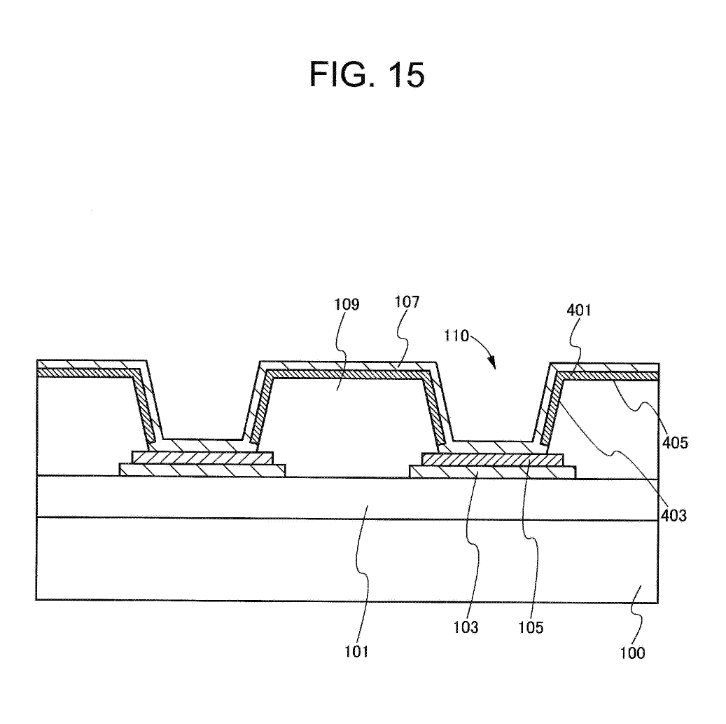

A configuration according to a fifth embodiment will be described with reference to FIG. 14 and FIG. 15. In the fifth embodiment, a reflective layer 401 is formed between a bank layer 109 and an upper electrode 107.

As illustrated in FIG. 14, the bank layer 109 has side surfaces 403 intersecting an opening 110. The side surfaces 403 are inclined so that the opening 110 increases with increasing distance from a substrate 100. The reflective layer 401 is arranged opposite to at least the side surface 403. In FIG. 14, the reflective layer 401 is arranged independently on each of the side surfaces 403. The reflective layer 401 is formed of a metal composed of aluminum, for example.

To efficiently utilize light emitted by a light emitting layer 105 for image display, more of the light needs to be extracted in a normal direction of a main surface of the substrate 100, i.e., a normal direction of a display surface of a display device 10. In the fifth embodiment, the reflective layer 401 is arranged on the side surface 403. Therefore, light emitted in an oblique direction different from the normal direction from the light emitting layer 105 can be reflected in the normal direction. As a result, light emitted by the light emitting layer 105 can be efficiently utilized for image display.

FIG. 15 illustrates a modification to the fifth embodiment. A configuration illustrated in FIG. 15 differs from the configuration illustrated in FIG. 14 in a position where a reflective layer 401 is arranged.

The reflective layer 401 illustrated in FIG. 15 is arranged to opposes each of side surfaces 403 of a bank layer 109 while also opposing an upper surface 405 of the bank layer 109. In FIG. 15, between adjacent two pixels, a reflective layer 401a opposing the side surface 403 located on the side of one of the pixels, a reflective layer 401b opposing the side surface 403 located on the side of the other pixel, and a reflective layer 401c opposing the upper surface 405 intersecting the side surfaces 403 are integrally formed. However, the present invention is not limited to this configuration. The configuration may be replaced with a configuration in which the reflective layer 401c is divided on the upper surface 405, for example.

Also in the configuration illustrated in FIG. 15, light emitted by a light emitting layer 105 can also be efficiently utilized for image display, like in the configuration illustrated in FIG. 14.

### Sixth Embodiment

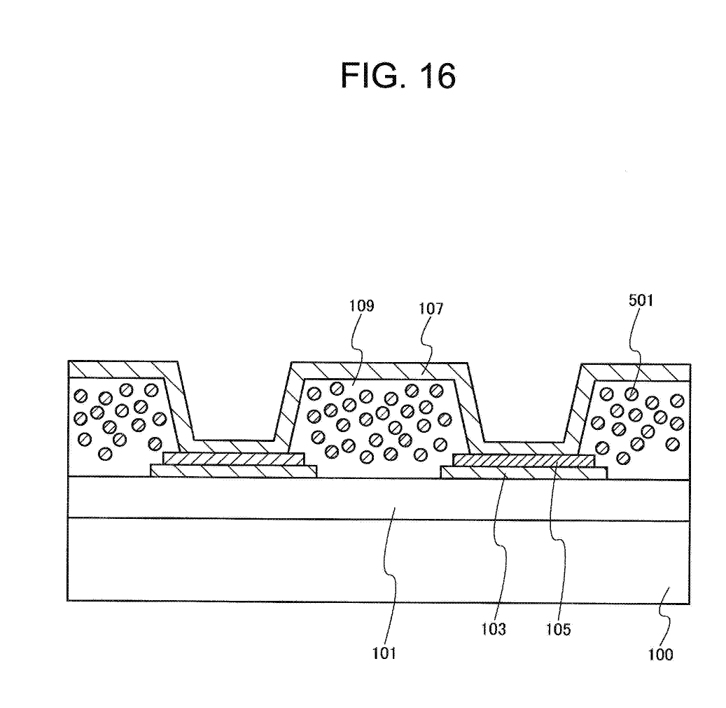

A configuration according to a sixth embodiment will be described with reference to FIG. 16. The sixth embodiment differs from the fifth embodiment in that a bank layer 109 contains light scattering particles 501 instead of the reflective layer 401.

As illustrated in FIG. 16, the bank layer 109 contains the light scattering particles 501. Light emitted by a light emitting layer 105 and incident on the bank layer 109 is scattered by the light scattering particles 501. As a result, an amount of light extracted in a normal direction of a main surface of a substrate 100 increases.

More specifically, the bank layer 109 contains the light scattering particles 501 in the sixth embodiment. Therefore, light emitted in an oblique direction different from the normal direction of the main surface of the substrate 100 from the light emitting layer 105 is scattered so that a traveling direction of the light can be changed to the normal direction. As a result, light emitted by the light emitting layer 105 can be efficiently utilized for image display.

While the first to sixth embodiments of the present invention have been described above, the scope of the present invention is not limited to only the first to sixth embodiments. Within the idea of the present invention, those skilled in the art could have easily conceived various alterations and modifications, and it is understood that the alterations and the modifications belong to the scope of the present invention. Addition, deletion, or design change of a component or components or addition, deletion, or condition change of a process or processes to each of the aforementioned embodiments performed, as needed, by those skilled in the art is also included in the scope of the present invention without departing from the spirit of the invention.

What is claimed is:

1. A method for manufacturing a display device, the method comprising:
a lower electrode formation step of forming a lower electrode on a substrate;
a coating step of coating the substrate with a light emitting layer;
a light emitting layer patterning step of patterning the light emitting layer into an island-shaped pattern at least a part of which overlaps the lower electrode;
an insulating layer formation step of forming an insulating layer which covers an upper surface and a side surface of the light emitting layer after the light emitting layer patterning step;
an opening formation step of forming an opening in the insulating layer, the opening exposing a part of the upper surface of the light emitting layer; and
an upper electrode formation step of forming an upper electrode located on the insulating layer and contacting the light emitting layer via the opening.

2. The method for manufacturing the display device according to claim 1, wherein
a plurality of pixels are provided on the substrate,
the insulating layer formation step includes forming the insulating layer in an entire area of the substrate, and
the opening formation step includes forming the opening in the insulating layer while patterning the insulating layer into such a shape that insulating layers after the patterning are located at boundaries among the plurality of pixels and separate the plurality of pixels.

3. The method for manufacturing the display device according to claim 1, wherein
a first pixel and a second pixel adjacent to the first pixel are provided on the substrate,
the first pixel includes a first light emitting layer having a first luminescent color,
the second pixel includes a second light emitting layer having a second luminescent color different from the first luminescent color,
the coating step includes a first coating step of coating the first light emitting layer, and a second coating step of coating the second light emitting layer,
the light emitting layer patterning step includes a first light emitting layer pattering step of patterning the first light emitting layer, and a second light emitting layer patterning step of patterning the second light emitting layer,
the first coating step, the first light emitting layer patterning step, the second coating step, and the second light emitting layer patterning step are performed in this order.

4. The method for manufacturing the display device according to claim 1, wherein
the insulating layer has a side surface intersecting the opening, and further comprising a reflective layer formation step of forming a reflective layer on the side surface.

5. The method for manufacturing the display device according to claim 1, wherein
the insulating layer has a region located on an opposite side of the light emitting layer from the lower electrode and covering a peripheral portion of the light emitting layer, the peripheral portion including an end portion of the light emitting layer, and
the opening exposes a central portion which is a portion other than the peripheral portion of the light emitting layer.
